(19) United States
(12) Patent Application Publication
(10) Pub. No.: US 2015/0034652 A1
(43) Pub. Date: Feb. 5, 2015

(54) CLAMP FASTENING FOR FASTENING A HOUSING TO A RAIL

(71) Applicant: Siemens Aktiengesellschaft, Muenchen (DE)

(72) Inventor: Martin Petricek, Hollabrunn (AT)

(21) Appl. No.: 14/378,008

(22) PCT Filed: Jan. 15, 2013
(86) PCT No.: PCT/EP2013/050626

§ 371 Date: Aug. 11, 2014

(30) Foreign Application Priority Data
Feb. 13, 2012 (EP) 12155061.0

(51) Int. Cl. H05K 7/14; H05K 7/18; H02G 5/02

(52) U.S. Cl. CPC H05K 7/14; H02G 5/025; H05K 7/183
USPC 220/324; 248/274.1; 248/221.11

(57) ABSTRACT

A clamp fastener for fastening a housing to a rail, such as a top-hat rail, includes a slider which is clampable to the rail, wherein, for simultaneous connection of the housing to an adjacent housing that is already fastened to the rail, the slider is transferable to the clamping position via a slider lock comprising an additional slider, which can be actuated by the adjacent housing, and the slider additionally includes a housing lock for locking the housing to the adjacent housing when transferring the slider to the clamping position.

### REFERENCE TO RELATED APPLICATIONS

This is a U.S. national stage of application No. PCT/EP2013/050626 filed 15 Jan. 2013. Priority is claimed on European Application No. 12155061 filed 13 Feb. 2012, the content of which is incorporated herein by reference in its entirety.

### BACKGROUND OF THE INVENTION

1. Field of the Invention

The invention relates to a clamp fastening for fastening a housing to a rail, such as a top-hat rail, having a slider which can be clamped to the rail.

2. Description of the Related Art

Fastenings are also referred to as snap-on fastenings. They are used in conjunction with rail-mounted devices, especially with switches from bus bar networks. Here, the rail-mounted device has a housing that has a shape advantageous for a bus bar network. On the one hand, for space reasons, an accumulation of the rail-mounted devices is supported by the housing of the rail-mounted device, which is designed as a switch or as a contactor, for example, allowing a planar arrangement of further housings on two or more sides and simultaneously having a clamp or snap-on fastening, which is intended for fastening the housing to a rail, i.e., a top-hat rail.

Such a switch or contactor is fixed to the top-hat rail with the aid of a slider. The problem here is that the top-hat rail is disposed on the side facing away from the user when the switch is being used and releasing it from the bus bar network is not something that can readily be performed because of the lack of access on account of switches in close spatial proximity to one another. As a consequence, conventional sliders have an actuation element that is always accessible to the user even in the installed state and also have a locking element that is disposed on the rear side of the housing in the vicinity of the rail. The two elements are connected via a connection area. The task of the connection area is to redirect the actuation force exerted by the user on the actuation element into the line of movement of the locking element.

At the same time, convenient methods of installation or dismantling of the switch are to be guaranteed. For dismantling, the actuation element of the switch is able to be moved in the direction of the user, where unlocking is guaranteed by a corresponding movement of the locking element.

Because of the complex form of the slider expensive, multi-part sliders have been used in the past. DE 297 10 310 U1 discloses a multi-part slider, which is divided into a locking part and a separate actuating part.

DE 10 2007 015 470 A1 discloses a snap-on fastening for fastening a housing to a rail with a slider, where the slider has an actuation element, a locking element and a connection area between the actuation element and the locking element for redirecting the direction of the actuation force that acts on the locking element via the connecting area. With the one-piece slider, at least the connecting area is embodied for elastic resetting.

Neither of the two publications DE 297 10 310 U1 and DE 10 2007 015 470 A1, however, provide a solution as to how a number of housings of the rail-mounted device can be connected to one another mechanically.

### SUMMARY OF THE INVENTION

It is an object of the present invention to make available a clamp fastening which not only clamps a housing to a rail but also clamps adjacent housings to one another.

This and other objects and advantages are achieved by providing a clamp fastening for fastening a housing to a rail is provided with a slider, where for simultaneous connection of the housing to an adjacent housing already fastened to the rail, the slider is able to be actuated via a slider lock comprising a further slider which is able to be actuated through the adjacent housing, is able to be transferred into the clamping position and the slider additionally has a housing lock for locking the housing with the adjacent housing during transfer of the slider into the clamping position.

Through this, when the housing with the slider in accordance with the invention is moved towards a housing already clamped to the rail, the slider lock is pushed by the wall of this adjacent housing into the housing and the slider is released. As a result, the slider can be moved from the open position into the clamping position and, during this movement, the housing lock is simultaneously brought into engagement with a corresponding mating piece on the adjacent housing. Thus, after the slider has the reached the clamping position the housing is also locked with the adjacent housing.

In such cases, there can be provision for the slider lock to be able to be moved in a straight-line direction, and indeed normal to any direction in which the slider is able to be moved into the clamping position. Thus, when the slider is located in the installed state on the rear wall of the housing and is brought into the clamping position from bottom to top, then the slider lock will be able to be moved horizontally, from left to right, for example.

In an embodiment of the invention, the slider lock has an element that can be pre-tensioned in the direction of movement of the slider lock, with which the slider lock is able to be fastened to the inner side of the housing. The pre-tensionable element can be a spring, e.g., a coil spring.

In an especially simple mechanical embodiment of the invention, the housing lock is connected rigidly to the slider. The housing lock can have openings that are suspended into suspension tabs of the slider. The same suspension tabs can simultaneously be used for guiding the slider in the housing.

If the slider is formed as a planar element it is inherently stable and can be manufactured easily, such as from a metal sheet. The slider then also has enough space if it is disposed on the rear side of the housing. Any tabs of the slider can be manufactured by bending the sheet metal. Planar here means that the length and width of the slider have the same order of magnitude and the thickness of the slider, including any suspension tabs, is only a fraction of the length or width, such as only around a quarter.

In an embodiment of the invention, the slider has at least one suspension tab which, to establish the clamping position of the slider, is able to be latched with a cutout of the slider lock. This represents a simple type of engagement between slider and slider lock. The same suspension tabs can simultaneously be used to guide the slider in the housing.

There can be provision for the slider—for holding the slider in the open position—to have an, especially exchangeable, latching hook. Thus, the slider can have tabs, over which a small plate with the latching hook is laid. This latching hook can then rest against a corresponding opening of the housing, as a rule in the rear wall, and hold the slider in the open position if the slider lock cannot fulfill this function because of its position. The latching hook, in the open position of the slider, can additionally be engaged with an extension of the slider lock which presses the latching hook in the direction towards the outside of the housing.

The clamp fastening in accordance with the invention is disposed in a housing so that the slider is supported movably in the housing in a straight-line direction (as a rule that direction which, in the clamping position of the housing on the rail, runs normal to the rail), so that the slider lock is supported movably in the housing at right angles thereto (as a rule that direction which, in the clamping position of the housing on the rail, runs parallel to the rail), so that the housing lock partly projects through the housing, where in the free position of the housing (i.e., if the housing could be moved on the rail) the slider lock projects beyond the housing and holds the pre-tensioned slider in the open position, while in the clamping position of the housing (i.e., if the housing were clamped rigidly on the rail) the slider lock is moved in relation to the open position into the inside of the housing and the slider is released.

This enables the slider, as a result of its pre-tensioning, to move in the direction towards the housing and it will assume its clamping position. Thus, when the housing is placed on the rail, the rail would grip the housing from behind and clamp the housing firmly onto the rail.

The housing lock makes it possible to hang the housing on the top-hat rail with the slider opened and still be able to move it along the top-hat rail.

The simplest arrangement of the slider is on the outer side of the housing and it is guided via suspension tabs in corresponding cutouts of the housing.

Accordingly, the slider lock could be supported to enable straight-line movement on the inner side of the housing and indeed normal to that direction in which the slider is able to be moved from the open position into the clamped position.

If the slider, for holding the slider in the open position, has an, especially exchangeable, latching hook which rests against the housing and holds the slider in the open position, this has the following advantage: During manual opening of the slider, the slider does not have to be held in the open position until such time as the housing is far enough from the adjacent housing for the slider as a result of its pre-tensioning (and the absence of the side part of the adjacent housing) to be moved far enough for it to hold the slider in the open position itself.

Other objects and features of the present invention will become apparent from the following detailed description considered in conjunction with the accompanying drawings. It is to be understood, however, that the drawings are designed solely for purposes of illustration and not as a definition of the limits of the invention, for which reference should be made to the appended claims. It should be further understood that the drawings are not necessarily drawn to scale and that, unless otherwise indicated, they are merely intended to conceptually illustrate the structures and procedures described herein.

### BRIEF DESCRIPTION OF THE DRAWINGS

For further explanation of the invention the reader is referred in the subsequent part of the description to the figures, from which further advantageous embodiments, details and developments of the invention are to be taken, in which:

FIG. 1 shows a view of an housing in the open position on a top-hat rail in accordance with the invention;

FIG. 2 shows the housing of FIG. 1 in the clamped position and locked with an adjacent housing;

FIG. 3 shows the housing of FIG. 1 or 2 during opening of the housing lock;

FIG. 4 shows the housing of FIGS. 1 to 3 after it moves away from the adjacent housing;

FIG. 5 shows a cross section of FIG. 1, where the slider is shown enlarged;

FIG. 6 shows a slider; and

FIG. 7 shows a latching hook.

### DETAILED DESCRIPTION OF THE PREFERRED EMBODIMENTS

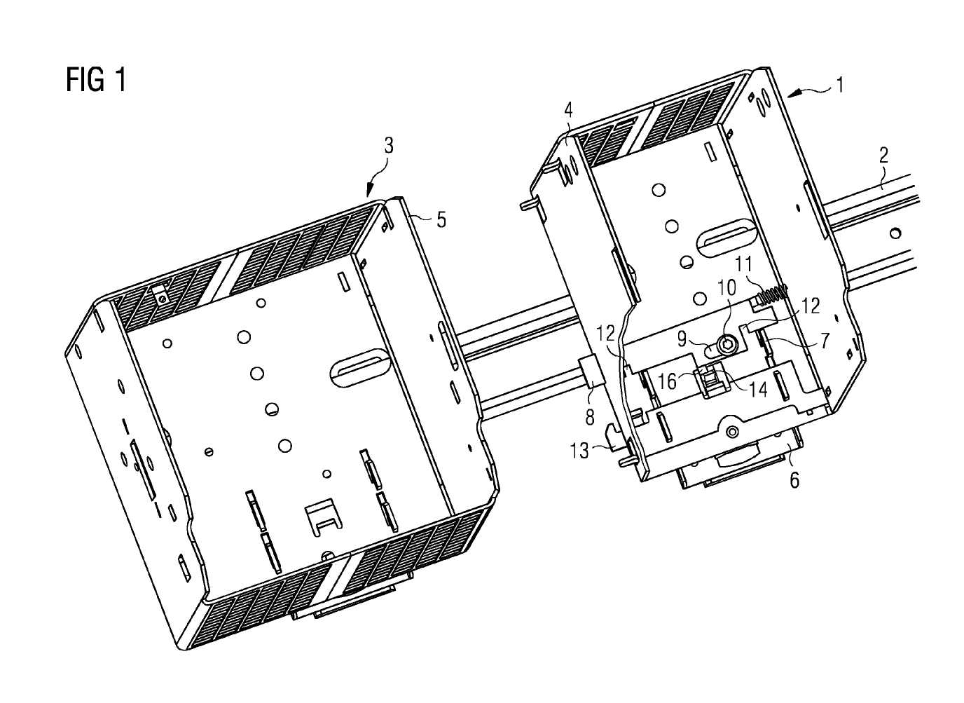

FIG. 1 shows an housing 1 in accordance with the invention which is placed on a top-hat rail 2 but is not clamped firmly onto the latter, however. The adjacent housing 3 shown to the left of housing 1 is already clamped firmly on the top-hat rail 2. The two housings have flat side walls 4, 5 that delimit the housing. The side walls 4, 5 are normal to the plane of the top-hat rail 2.

The slider 6 is disposed outside the housing 1, i.e., on its rear wall, and projects behind the housing 1, here on the lower. side, so that it can also be actuated (moved) by hand. The slider 6 could also be disposed on the rear wall of the housing 1 so that it projects upwards above the housing on the upper side of the housing.

The slider 6 has at least one suspension tab 7 on each of its long sides, which are aligned towards the housing 1 and are threaded through corresponding openings into the rear wall of the housing. The suspension tabs 7 serve as a guide for the slider 6, the right and left upper suspension tab 7 also rests however in FIG. 1 against the slider lock 8. In this position, its open position, i.e., the slider 6 is pre-tensioned.

The slider lock 8 is an elongated, essentially flat part, made of sheet metal, for example, which is guided via a slot 9, and is guided in parallel to the rear wall by a pin or by a screw 10, which is fastened in the rear wall of the housing 1. The (right-hand) end of the slider lock 8 located inside the housing is connected via a coil spring 11 to the right-hand side wall of the housing 1. The coil spring 11 is not under tension in this position of the slider lock 8. The right-hand side wall of the housing 1 serves as a stop for the (right-hand) end of the slider lock 8 located inside the housing when the slider lock is tensioned.

The other (left-hand) end of the slider lock 8 projects through an opening of the housing 1, more precisely through its side wall 4, and projects as far as the suspension tabs 7, in the longitudinal direction of the slider lock 8, are at a distance from the cutouts 12.

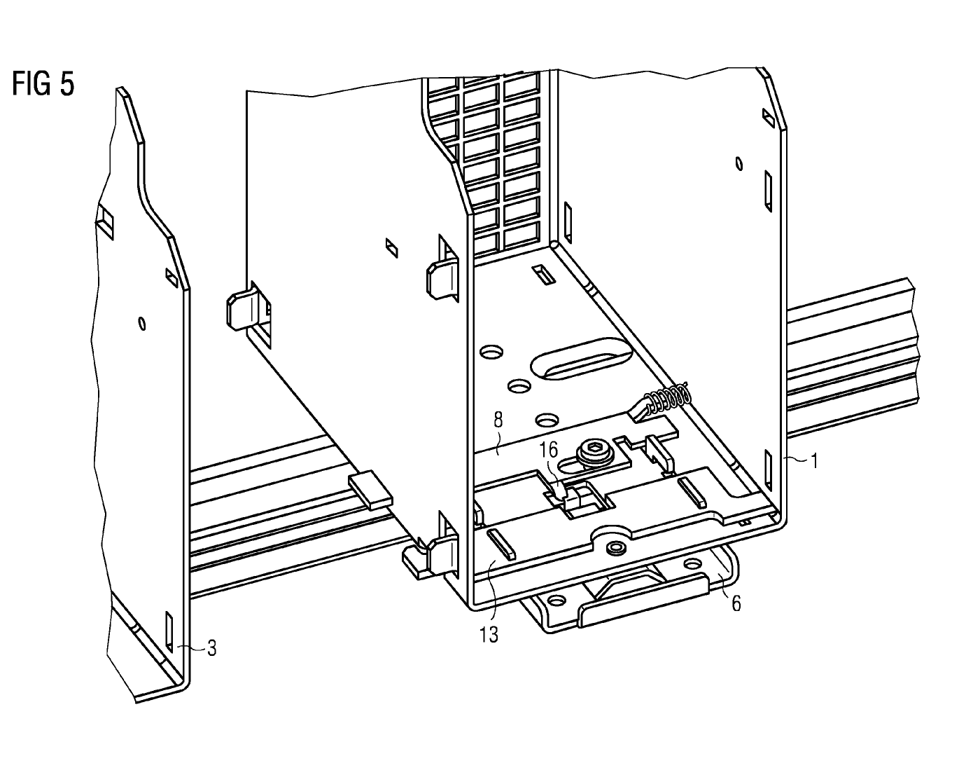

The housing lock 13, of which only a hook bent upwards is visible here, is formed as a flat strip and has openings through which the lower suspension tabs 7 of the slider 6 project, see also FIG. 5, and in this way they connect the housing lock 13 rigidly to the slider 6. The housing lock 13 can be formed, for example, as a strip of sheet metal, but it can also be manufactured via die-casting or in plastic via plastic injection molding.

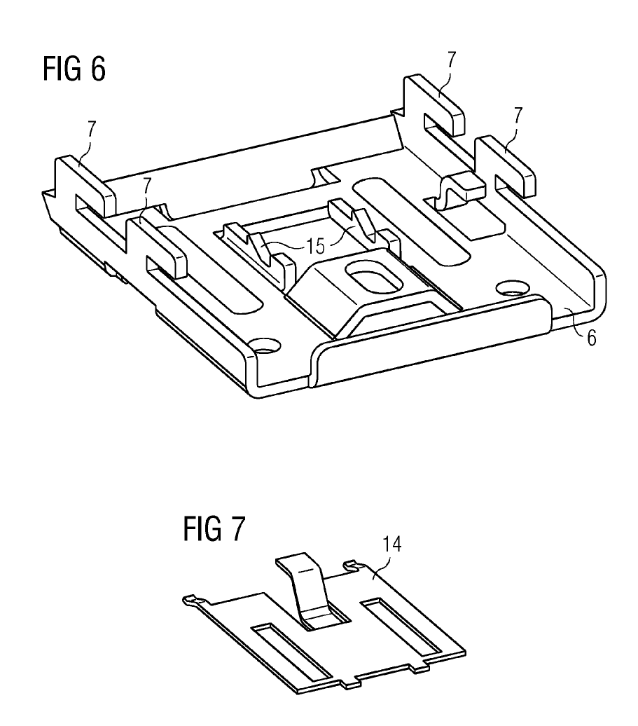

Also provided on the slider 6 is a (here exchangeable) latching hook 14, which likewise holds the slider in the open position. In this case, the latching hook 14 rests against a cutout or a similar device on the rear wall of the housing. The latching hook 14 is suspended via cutouts in corresponding tabs 15 of the slider 6, see FIG. 6, and is fixed by the housing lock 13 partly disposed above the hook. The latching hook 14 could, however, likewise be formed in one piece with the slider 6 or be connected to the slider so that it cannot be released.

Provided in the central area of the slider lock 8 is an extension that engages with the latching hook 14 in the open position of the slider and pushes the latching hook in the direction of the outer side of the housing.

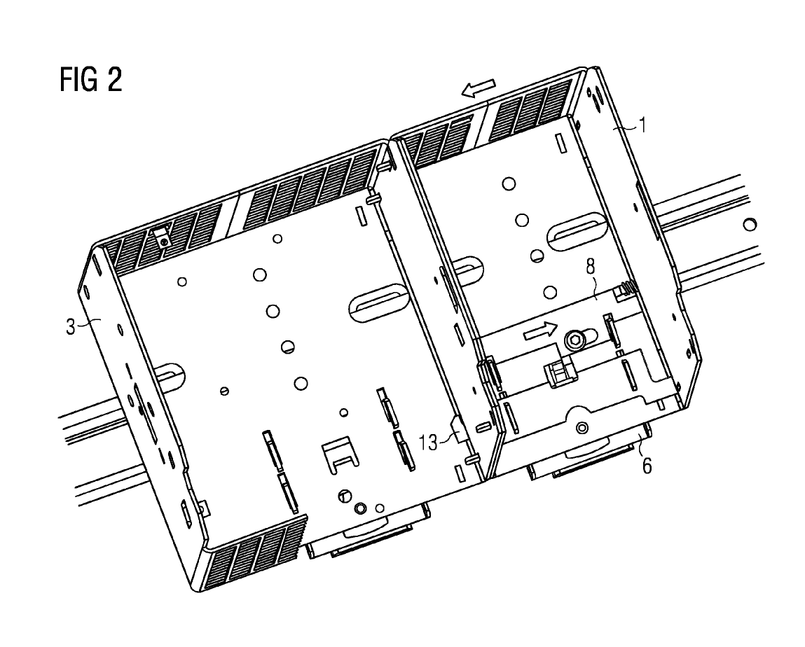

If the housing 1 is now moved to the left on the top-hat rail 2 towards the adjacent housing 3 (see arrow in FIG. 2) the side walls 3, 4 of the two housings 1, 3 approach each other. The side wall 3 then pushes the slider lock 8 into the housing 1 (to the right), see arrow in FIG. 2, and also far enough for the upper suspension tabs 7 of the pre-tensioned slider 6 to latch into the cutouts 12, the pre-tensioned slider 6 is released. Furthermore, the slider lock 8 cannot be pushed into the housing 1 because the right-hand end of the slider lock 8 is already touching the right side wall of the housing 1. Through the movement of the slider lock 8 the coil spring 11 is tensioned. The slider 6 progresses along the rear-wall upwards into its clamping position and clamps the housing 1 firmly onto the top-hat rail 2. The slider 6 is now in its non-tensioned position.

However the device lock 13 also moves upwards with the slider 6, where the hook projects from the housing 1 into the adjacent housing 3 hooks into the side wall 5 and thus connects the two housings 1, 3 mechanically to one another. This defines their mutual position in the direction of the top-hat rail 2. The latching hook 14 moves during the movement of the slider 6 behind the rear wall of the housing. FIG. 2 shows the clamping position just described.

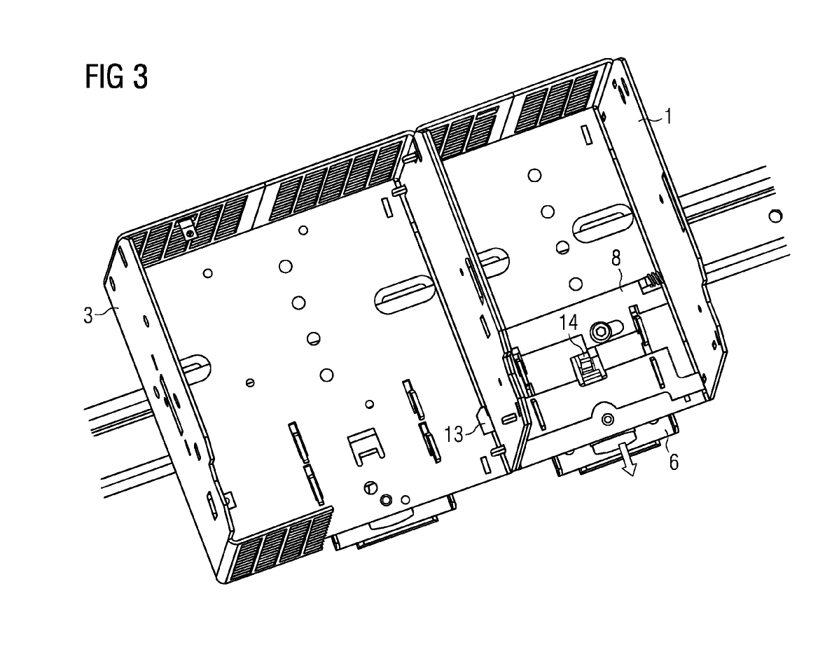

If the two housings 1, 3 are to be released from one another again and the housing 1 is to be moved to the right, the slider 6 is pushed away by hand downwards from the housing 1, i.e., in the direction shown by the arrow in FIG. 3, it is released. This causes the housing lock 13 to release from the side wall 5, i.e., to open, and it can be pulled out to the right through the opening of the side wall 5.

Pulling out the slider 6 also releases the clamping position, however the slider 6 cannot yet (as in FIG. 1) rest against the slider lock (although its position corresponds to that in FIG. 1), because the slider lock 8 cannot yet slide out of the housing 1 (to the left), it is still pushed by the side wall 5 into the housing 1 (to the right).

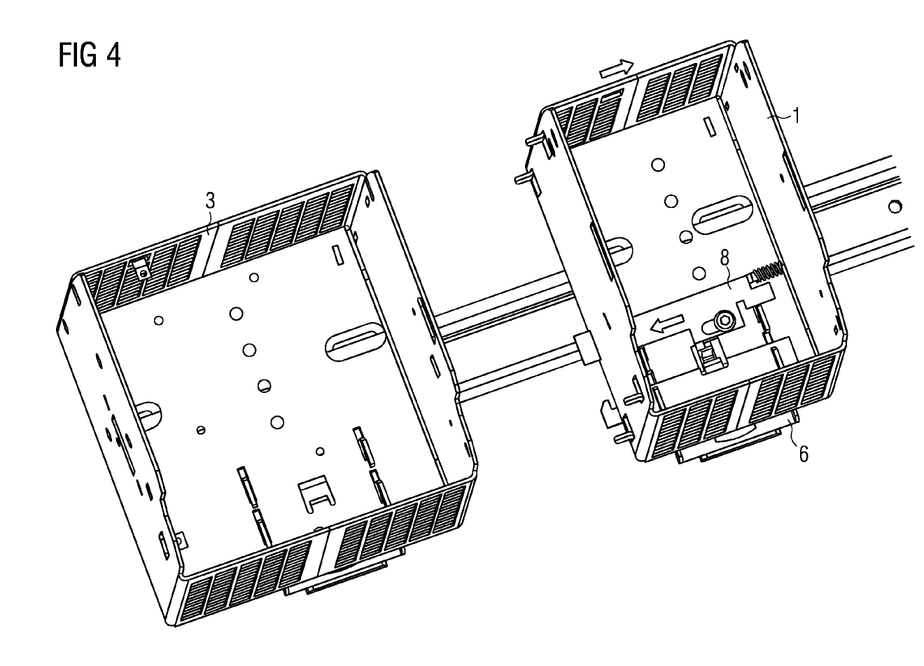

However, the position of the latching hook 14 is selected so that the latching hook rests on an opening of the rear wall and thus holds the slider 6, now pre-tensioned again, in the open position. The housing 1 can now (without the slider 6 constantly having to be held by hand in the open position) be moved along the top-hat rail 2 (see arrow at the top in FIG. 4).

As soon as the two side walls 4, 5 have moved far enough apart from each other the coil spring 11 pushes the slider lock 8 far enough out of the housing 1 again (to the left, see arrow in FIG. 4), until the slider 6 can again be held by the slider lock 8 in the open position. The pre-tensioned slider 6 is partly released by the latching hook 14. The same state as in FIG. 1 is thus established again.

In FIG. 5, the housing lock 13 and its fastening to the slider 6 are able to be seen more easily than in FIG. 1.

FIG. 6 shows the slider 6 with its four suspension tabs 7. Furthermore, the two tabs 15 for the latching hooks 14 are also seen. The latching hook 14 has a flat part with two slots that fit over the tabs 15, and thus fix the latching hook 14 simply by insertion into the slider 6 in the plane of the slider. The fixing normal to the plane of the slider 6 is done by the housing lock 13, see FIG. 1, for example.

While there have been shown, described and pointed out fundamental novel features of the invention as applied to a preferred embodiment thereof, it will be understood that various omissions and substitutions and changes in the form and details of the methods described and the devices illustrated, and in their operation, may be made by those skilled in the art without departing from the spirit of the invention. For example, it is expressly intended that all combinations of those elements and/or method steps which perform substantially the same function in substantially the same way to achieve the same results are within the scope of the invention. Moreover, it should be recognized that structures and/or elements and/or method steps shown and/or described in connection with any disclosed form or embodiment of the invention may be incorporated in any other disclosed or described or suggested form or embodiment as a general matter of design choice. It is the intention, therefore, to be limited only as indicated by the scope of the claims appended hereto.

1-11. (canceled)

12. A clamp fastening for fastening a housing to a rail having a slider which is clampable on the rail, comprising:
a slider lock comprising a further slider, which is actuateble through an adjacent housing such that the slider is transferrable into a clamping position for simultaneous connection of the housing with an adjacent housing pre-fastened to the rail; and
a housing lock engaging the slider for locking the housing with the adjacent housing when the slider is moved into the clamping position.

13. The clamp fastening as claimed in claim 12, wherein the slider lock is moveable in a straight line and at right angles to that direction in which the slider is moveable into the clamping position.

14. The clamp fastening as claimed in claim 12, wherein the slider lock includes an element which is pre-tensionable in a direction of movement of the slider lock, said element permitting fastening of the slider lock to an inner side of a housing.

15. The clamp fastening as claimed in claim 13, wherein the slider lock includes an element which is pre-tensionable in a direction of movement of the slider lock, said element permitting fastening of the slider lock to an inner side of a housing.

16. The clamp fastening as claimed in claim 12, wherein the housing lock is rigidly connected to the slider.

17. The clamp fastening as claimed in claim 12, wherein the slider is planar.

18. The clamp fastening as claimed in claim 12, wherein the slider includes at least one suspension tab which is lockable to establish the clamping position of the slider with a cutout of the slider lock.

19. The clamp fastening as claimed in claim 12, wherein the slider includes an exchangeable latching hook for holding the slider in the open position.

20. The clamp fastening as claimed in one of claim 12, wherein the rail is a top-hat rail.

21. A housing including the clamp fastening as claimed in claim 12, wherein the slider is supported to allow movement in a straight-line direction in the housing and movement in right angle directions thereto in the housing, wherein the housing lock partly projects through the housing, and wherein, in a free position of the housing, the slider lock projects beyond the housing and holds the pre-tensioned slider in the open position, while in the clamping position of the housing the slider lock is moved in relation to the open position into an inside of the housing and the slider is released.

22. The housing as claimed in claim 21, wherein the slider is disposed on an outer side of the housing and is guided via suspension tabs in corresponding cutouts of the housing.

23. The housing as claimed in claim 21, wherein the slider lock is supported to allow movement in a straight-line direction on the inside of the housing and to allow movement at right angles to that direction in which the slider movable from the open position into the clamped position.

24. The housing as claimed in claim 22, wherein the slider lock is supported to allow movement in a straight-line direction on the inside of the housing and to allow movement at right angles to that direction in which the slider movable from the open position into the clamped position.

25. The housing as claimed in claim 21, wherein the slider includes, for holding the slider in the open position, an exchangeable, latching hook which rests against the housing and holds the slider in an open position.
